(19) United States
(12) Patent Application Publication
(10) Pub. No.: US 2023/0078458 A1
(43) Pub. Date: Mar. 16, 2023

(54) SEMICONDUCTOR DEVICE

(71) Applicant: EPISTAR CORPORATION, Hsinchu (TW)

(72) Inventors: Wei-Jen Hsueh, Hsinchu (TW); Shih-Chang Lee, Hsinchu (TW)

(21) Appl. No.: 17/940,662

(22) Filed: Sep. 8, 2022

(30) Foreign Application Priority Data
Sep. 10, 2021 (TW) 110133672

(51) Int. Cl. H01L 31/0304; H01L 31/105

(52) U.S. Cl. CPC H01L 31/03042; H01L 31/105

(57) ABSTRACT

A semiconductor device includes a dielectric layer, a first trench located in the dielectric layer, a first semiconductor located in the first trench, a second semiconductor layer and an electrical connector. The dielectric layer has a first surface. The second semiconductor layer includes an active portion connecting the first semiconductor layer, and the electrical connector is located on the first surface and connects the second semiconductor layer.

### TECHNICAL FIELD

The disclosure relates to a semiconductor device, and particularly to a III-V semiconductor device for emitting or absorbing lights.

### CROSS REFERENCE TO RELATED APPLICATION

This application claims the right of priority based on TW Application Serial No. 110133672, filed on Sep. 10, 2021, and the content of which is hereby incorporated by reference in its entirety.

### DESCRIPTION OF BACKGROUND ART

In the field of semiconductors, silicon-based semiconductor components have advantages of mature manufacture technology, while III-V semiconductor components have benefits of special material properties like high carrier mobility or special optoelectronic performance. However, due to the problem of lattice matching, there are many challenges in integrating III-V group semiconductor elements and silicon-based semiconductor elements into an optoelectronics integrated circuits (OEIC). Nowadays, with the improvement of multi-chip module (MCM) bonding and die bonding technology, it has been possible to reduce the electrical signal transmission distance between components to about 10² μm, and these technologies can be widely used in fields of display, sensing devices, augmented reality and virtual reality.

### SUMMARY OF THE DISCLOSURE

The present disclosure provides a semiconductor device. The semiconductor device includes a dielectric layer having a first surface, a first trench located in the dielectric layer, a first semiconductor located in the first trench, a second semiconductor layer and an electrical connector located on the first surface. The second semiconductor layer includes an active portion connecting the first semiconductor layer, while the electrical connector connects the second semiconductor layer.

The present disclosure also provides a semiconductor apparatus. The semiconductor apparatus includes a substrate, the semiconductor device mentioned above and a transistor. The substrate includes a first sublayer. The transistor includes a fin, wherein the fin and the first sublayer include the same material.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIGS. 1A-1H show schematic diagrams of manufacturing process of a semiconductor device disclosed in one embodiment in accordance with the present disclosure;

FIGS. 1I-1J show schematic diagrams of manufacturing process of a semiconductor device disclosed in one embodiment in accordance with the present disclosure;

FIGS. 1K-1N show schematic diagrams of manufacturing process of a semiconductor device disclosed in one embodiment in accordance with the present disclosure;

FIGS. 2A-2H show top views of manufacturing process of a semiconductor device corresponding to FIGS. 1A-1H;

FIG. 3A shows a cross-sectional view of a semiconductor device disclosed in one embodiment in accordance with the present disclosure;

FIG. 3B shows a cross-sectional view of a semiconductor device disclosed in one embodiment in accordance with the present disclosure;

FIG. 3C shows a cross-sectional view of a semiconductor device disclosed in one embodiment in accordance with the present disclosure;

FIG. 3D shows a cross-sectional view of a semiconductor device disclosed in one embodiment in accordance with the present disclosure;

FIG. 4 shows a cross-sectional view of a semiconductor device disclosed in one embodiment in accordance with the present disclosure;

FIG. 5 shows a cross-sectional view of a semiconductor device disclosed in one embodiment in accordance with the present disclosure;

FIG. 6 shows a cross-sectional view of a semiconductor device disclosed in one embodiment in accordance with the present disclosure;

FIG. 7 shows a cross-sectional view of a semiconductor device disclosed in one embodiment in accordance with the present disclosure;

FIG. 8 shows a cross-sectional view of a semiconductor device disclosed in one embodiment in accordance with the present disclosure;

FIG. 9 shows a cross-sectional view of a semiconductor device disclosed in one embodiment in accordance with the present disclosure;

FIG. 10 shows a cross-sectional view of a semiconductor device disclosed in one embodiment in accordance with the present disclosure;

FIG. 11 shows a cross-sectional view of a semiconductor device disclosed in one embodiment in accordance with the present disclosure;

FIG. 12 shows a cross-sectional view of a semiconductor apparatus disclosed in one embodiment in accordance with the present disclosure;

FIGS. 13A-13D show schematic diagrams of manufacturing process of a semiconductor apparatus disclosed in one embodiment in accordance with the present disclosure;

FIG. 14 shows a perspective view of a semiconductor apparatus disclosed in one embodiment in accordance with the present disclosure.

### DETAILED DESCRIPTION OF PREFERRED EMBODIMENTS

Exemplary embodiments of the present disclosure will be described in detail with reference to the accompanying drawings hereafter. The following embodiments are given by way of illustration with Cartesian Coordinates (X, Y, Z axes) to help those skilled in the art fully understand the spirit of the present disclosure. Hence, it should be noted that the present disclosure is not limited to the embodiments herein and can be realized in various forms. Further, the drawings are not precise scale and components may be exaggerated in view of width, height, length, etc. Herein, the similar or identical reference numerals will denote the similar or identical components throughout the drawings. In the embodiments of the present disclosure, if not described otherwise, the term “horizontal” means any value or vector along X-axis, Y-axis or on X-Y plane, while the term “vertical” means any value or vector along Z-axis. The terms such as “below”, “above”, “under”, “on”, “top” and “bottom” may be used to describe special relationships along Z-axis between different devices or elements. The terms “corresponding” and “cover” may be used to describe different elements are overlapped horizontally (on X-Y plane). The term “coplanar” may be used to describe surfaces of different elements are vertically on the same level.

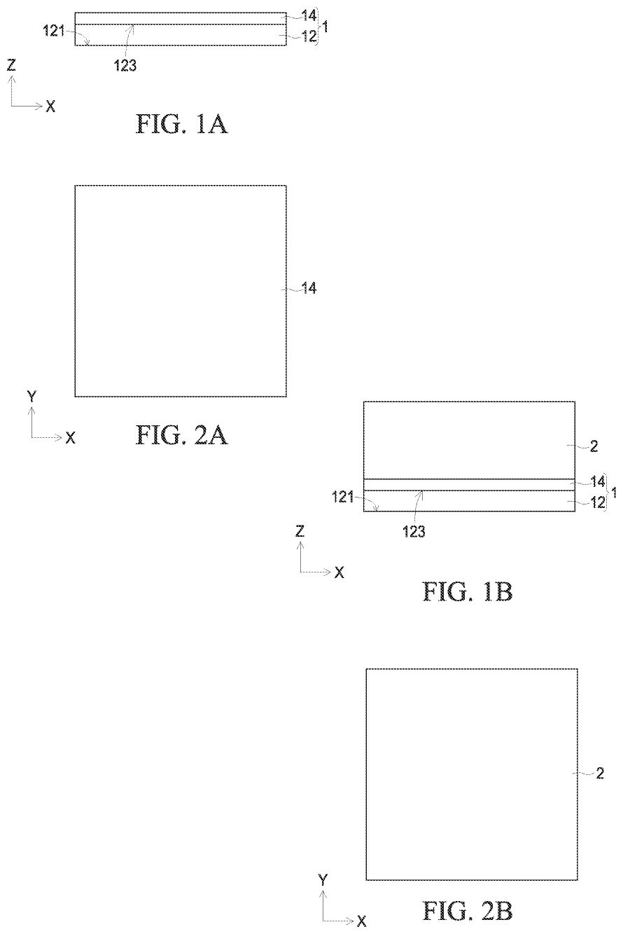

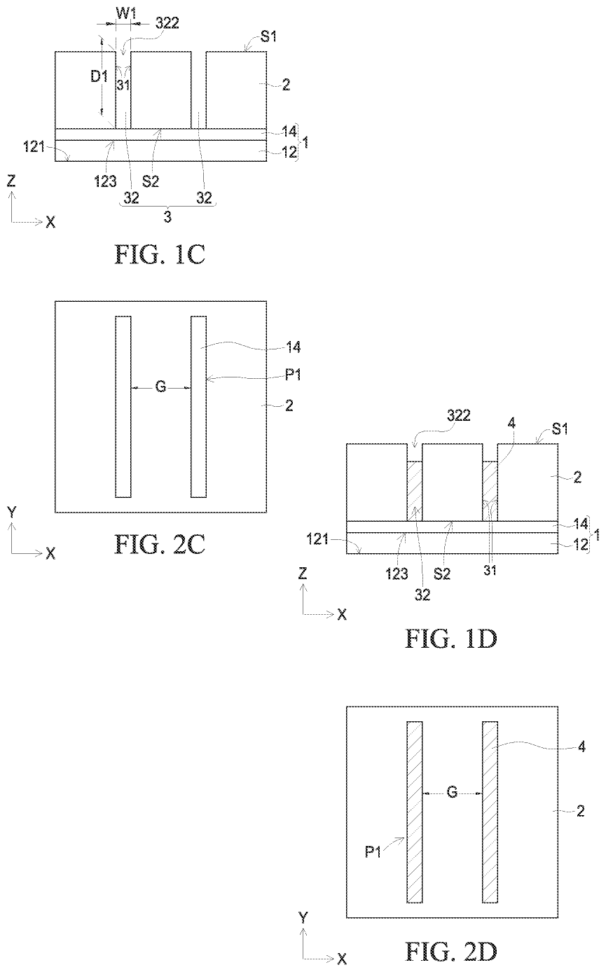

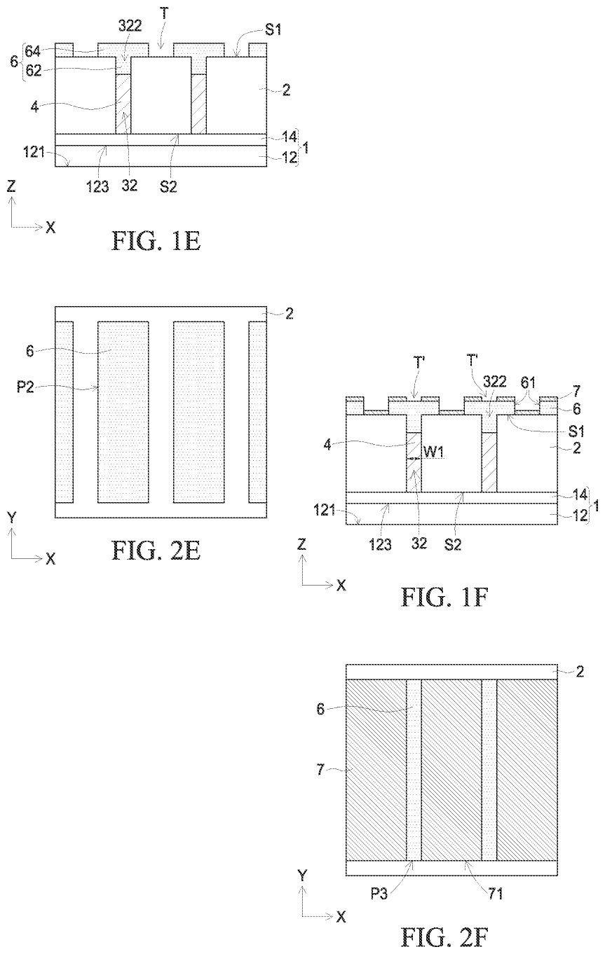

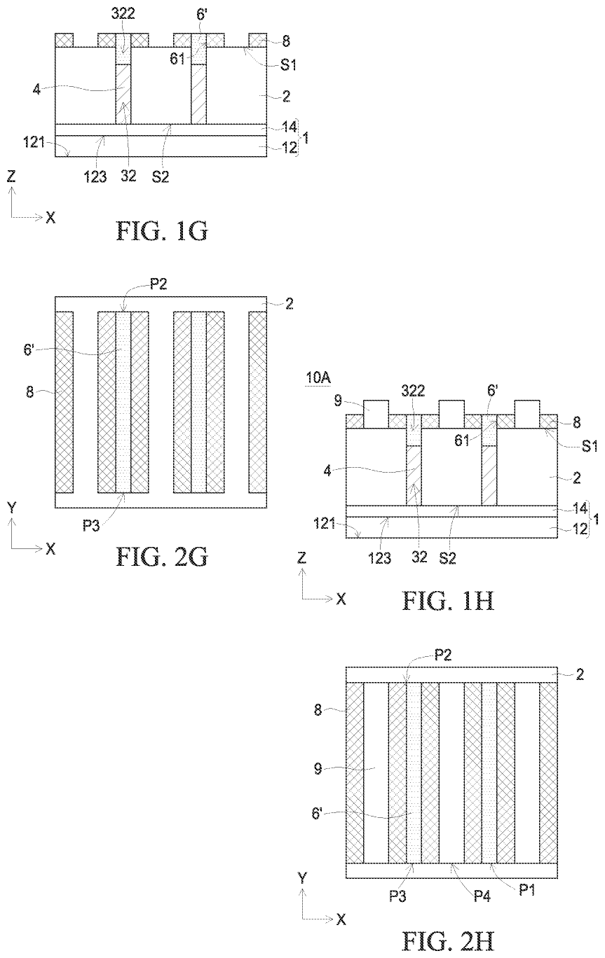

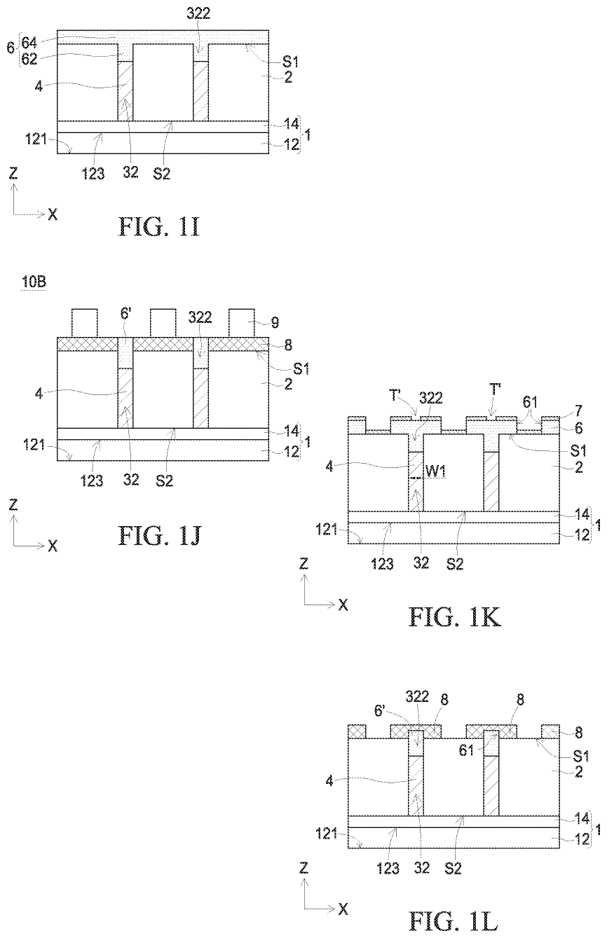

FIGS. 1A-1H are schematic diagrams of manufacturing process of a semiconductor device 10A in one embodiment in accordance with the present disclosure and FIGS. 2A-2H are top views of the semiconductor device 10A respectively corresponding to steps of FIGS. 1A-1H. The semiconductor device 10A can be a light-emitting device, a light-absorbing device or other devices, such as a light-emitting diode, a laser diode, a photodetector or a solar cell.

In the process step shown in FIG. 1A, a substrate 1 is provided. The substrate 1 includes a base layer 12 and a first sublayer 14. The base layer 12 includes a bottom surface 121 and a top surface 123 opposite to the bottom surface 121, and the first sublayer 14 is located on the top surface 123. In one embodiment, the substrate 1 only includes the base layer 12 or the first sublayer 14. Besides, the substrate 1 can have various shapes in accordance with requirements of design, process or other factors. In the embodiment shown in FIG. 2A, the substrate 1 is square, but the substrate 1 can be provided in other shapes, such as circle, rectangle, polygon or irregular shape.

In the process step shown in FIG. 1B, a dielectric layer 2 is formed on the substrate 1. More specifically, the dielectric layer 2 is formed on the first sublayer 14 through a deposition process, such a physical vapor deposition (PVD), chemical vapor deposition (CVD), atomic layer deposition (ALD) or other deposition technology. As shown in FIGS. 1B and 2B, the first sublayer 14 is fully covered by the dielectric layer 2, and the dielectric layer 2 and the first sublayer 14 have the same area in top-view. Moreover, optionally, a thermal oxidation process can be implemented to the dielectric layer 2 to enhance insulation property. In one embodiment, the first sublayer 14 can be formed with a larger thickness then partially or fully transformed into the dielectric layer 2 through the thermal oxidation process. For example, the first sublayer 14 can be Si, and the dielectric layer 2 can be SiO₂.

In the process step shown in FIG. 1C, a trench structure 3 is formed in the dielectric layer 2. Specifically, the dielectric layer 2 has a first surface S1 away from substrate 1, and the trench structure 3 is formed by patterning the first surface S1 through nanoimprint lithography (NIL) technology. The trench structure 3 includes a plurality of first trenches 32, and each of the first trenches 32 includes a trench sidewall 31 and a first opening 322 located on the first surface S1. The first trench 32 penetrates the dielectric layer 2 to expose a second surface S2 of the first sublayer 14 which facing the dielectric layer 2. In one embodiment, the second surface S2 has a specific crystal plane such as (111), and the trench sidewall 31 also has specific crystal planes such as {110} plane family. Through high resolution transmission electron microscopy (HRTEM), the diffraction pattern of (111) and {110} may be dot, while the diffraction pattern of 11101 after thermal oxidation process may be arc or circle. Referring to FIG. 2C, the first trench 32 has a first contour P1 in the top view (on the X-Y plane), and the first contour P1 is rectangle. In other embodiments, the first contour P1 can be formed in other shapes, such as circle, quadrangle, pentagon, hexagon or irregular shape.

As shown in FIG. 1C, the first trench 32 also has a first depth D1 and a first width Wl. The first depth D1 can be in a range of 10 nm to 5000 nm, such as 50 nm, 100 nm, 200 nm, 300 nm 400 nm, 500 nm, 1000 nm, 2000 nm or 4000 nm. The first width W1 can be in a range of 10 nm to 3000 nm, such as 50 nm, 100 nm, 150 nm 200 nm, 300 nm, 500 nm, 1000 nm or 2000 nm. In addition, a ratio of the first depth D1 to the first width W1 can be between 0.033 to 50, such as 1, 5, 10, 20 or 40. Moreover, as shown in FIG. 2C, the first trenches 32 can be horizontally arranged (along X-axis) and are separated from each other by a gap G. The gap G can be between 0.1 μm to 10 μm, such as 0.5 μm, 1 μm or 5 μm.

In the process step shown in FIGS. 1D and 2D, a first semiconductor layer 4 is formed in each of the first trenches 32 by an epitaxy process. In detail, the first semiconductor layer 4 can be formed by an epitaxy process supplemented by aspect ratio trapping (ART) technology. The epitaxy process can be implemented by various technology, such as metal-organic chemical vapor deposition (MOCVD), molecular beam epitaxy (MBE), hydride vapor epitaxy (HVPE) or other methods. In one embodiment, since the trench sidewall 31 has specific crystal planes like aforementioned {110} plane family, the crystal growth speed in vertical direction (along Z-axis) can be much faster than that in horizontal direction (along X-axis or Y-axis).

In the process step shown in FIGS. 1E and 2E, a second semiconductor layer 6 is formed on the first semiconductor layer 4 by another epitaxy process. Specifically, by epitaxy technology such as epitaxial lateral overgrowth (ELOG), the second semiconductor layer 6 is formed on the first semiconductor layer 4 and fills the first trench 32. Moreover, the second semiconductor layer 6 may protrude from the first trench 32 and extend to the first surface S1 of the dielectric layer 2 to cover the first opening 322. Thus, the second semiconductor layer 6 includes a first section 62 located in the first trench 32 and a second section 64 protruding from the first trench 32. In one embodiment, the second semiconductor layer 6 is a discontinuous film including multiple blocks separated from each other by a first space T so the second semiconductor layer 6 covers parts of the first surface S1. In the top view of FIG. 2E, each block of the second semiconductor layer 6 has a second contour P2, which is larger than the first contour P1 of the first trench 32.

In the process step shown in FIGS. 1F and 2F, a doped layer 7 including a first dopant is formed on the second semiconductor layer 6 by deposition process. The doped layer 7 is formed with a pattern so the doped layer 7 includes multiple blocks which are separated from each other by a second space T′. In one embodiment, the second space T′ is disposed corresponding to the first opening 322 and has a width approximately equal to the first width W1 of the first opening 322. In the top view of FIG. 2F, each block of the doped layer 7 has a doped layer contour 71, and the second semiconductor layer 6 exposed by the second space T′ has a third contour P3. The doped layer contour 71 and the third contour P3 are alternatively arranged along X-axis. In another embodiment, the second semiconductor layer 6 has side surfaces 61, and the doped layer 7 can optionally cover the side surfaces 61 to effectively diffuse the first dopant into the second semiconductor layer 6 so the diffusion uniformity is improved.

In the process step shown in FIGS. 1G and 2G, the first dopant in the doped layer 7 is diffused into the second semiconductor layer 6 by a thermal process to form an active portion 6′ and a doped portion 8 in the second semiconductor layer 6, and then the remaining doped layer 7 is removed by an etching process. The active portion 6′ is located corresponding to the first trench 32, while the doped porting 8 connects the active portion 6′ without covering the first opening 322. In this embodiment, the doped portion 8 includes the first dopant diffused from the doped layer 7 and has a first conductivity type, and the concentration of the first dopant is greater than 10¹⁶cm⁻³, such as 10¹⁷cm⁻³, 10¹⁸cm⁻³, 10¹⁹cm⁻³ or 10²⁰cm⁻³. Besides, the first semiconductor layer 4 includes a second dopant and has a second conductivity type different from the first conductivity type, and the concentration of the second dopant is greater than 10¹⁶cm⁻³, such as 10 ¹⁷cm⁻³, 10¹⁸cm⁻³, 10¹⁹cm⁻³ or 10²⁰cm⁻³. The first conductivity type and the second conductivity type can be p-type and n-type, or n-type and p-type. In one embodiment, the doped portion 8, the first semiconductor layer 4 and the active portion 6′ are respectively p-type, n-type and i-type (un-doped), so as to form a p-i-n type diode.

In the process step shown in FIGS. 1H and 2H, an electrical connector 9 is formed on the first surface S1 of the dielectric layer 2 by evaporation or sputtering process to form the semiconductor device 10A. In this embodiment, there is a plurality of electrical connectors 9. In the top view, the electrical connector 9 has a fourth contour P4. Referring to FIGS. 2D and 2H, the first contour P1, the second contour P2, the third contour P3 and the fourth contour P4 can be quadrangle like rectangle or square, and respectively have a first area A1, and second area A2, a third area A3 and a fourth area A4. In this embodiment, the first area A1 is equal to the third area A3, and the fourth area A4 is greater than the third area A3. In one embodiment, the first area A1 is equal to or smaller than the second area A2, the third area A3, or the fourth area A4. In another embodiment, the fourth area A4 is smaller than the third area A3.

FIG. 11 depicts an alternative of the process step of FIG. 1E. In this embodiment, the second semiconductor layer 6 is continuous. Afterwards, following the process steps shown in FIGS. 1F-1H and appropriately implementing lithography, etching, deposition or diffusion processes to form the doped portion 8 and the electrical connector 9, a semiconductor device 10B as shown in FIG. 1J is formed.

FIGS. 1K-1N show alternatives of the process steps of FIGS. 1F-1H. Referring to FIG. 1K, the doped layer 7 is discontinuous with the second space T′ corresponding to the first opening 322. In this embodiment, the second space T′ has a width smaller than the first width W1 of the first opening 322 so the second semiconductor layer 6 above the first opening 322 is partially covered by the doped layer 7.

Afterwards, as shown in FIG. 1L, the doped portion 8 and the active portion 6′ are formed by thermal process and the doped layer 7 is removed by etching process. In this embodiment, the doped portion 8 is formed as a reverse-U shape to cover the active portion 6′. The doped portion 8 can be formed in various thickness and shapes by adjusting the width of the second space T′.

Referring to FIG. 1M, the doped portion 8 above the first opening 322 is partially removed by a dry etching process such as inductively coupled plasma (ICP) technology so that a cavity U is formed to expose a part of the active portion 6′ above the first opening 322. In this embodiment, the doped portion 8 covered on the active portion 6′ above the first opening 322 can protect the active portion 6′ from being damaged by external or environmental stress. At last, as shown in FIG. 1N, the electrical connector 9 is formed on the first surface S1 to obtain a semiconductor device 10C.

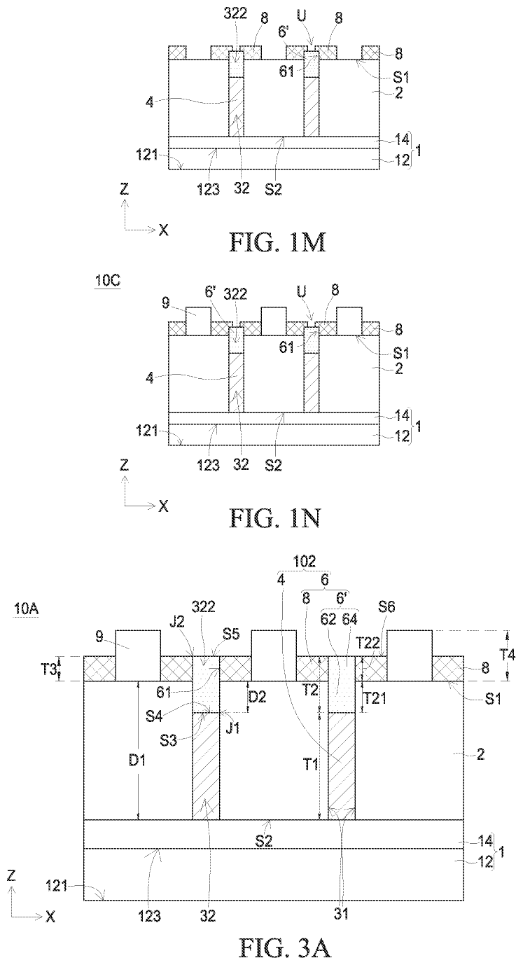

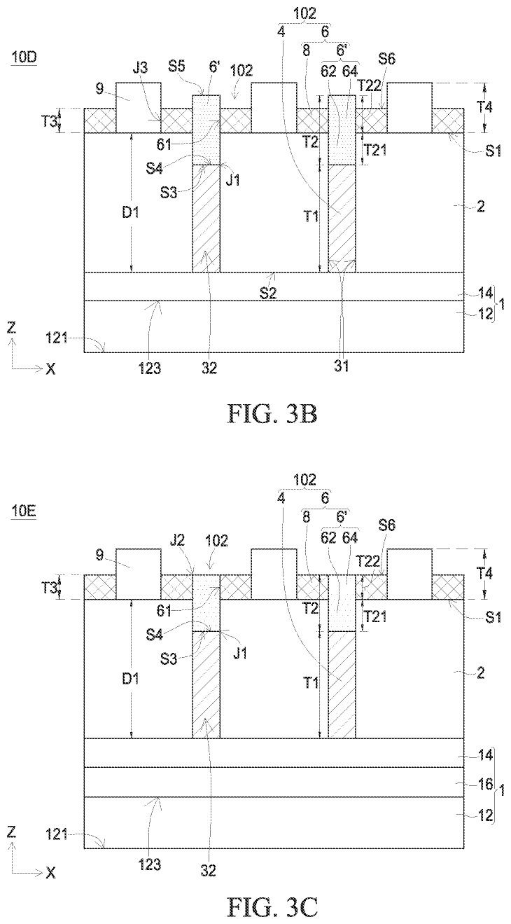

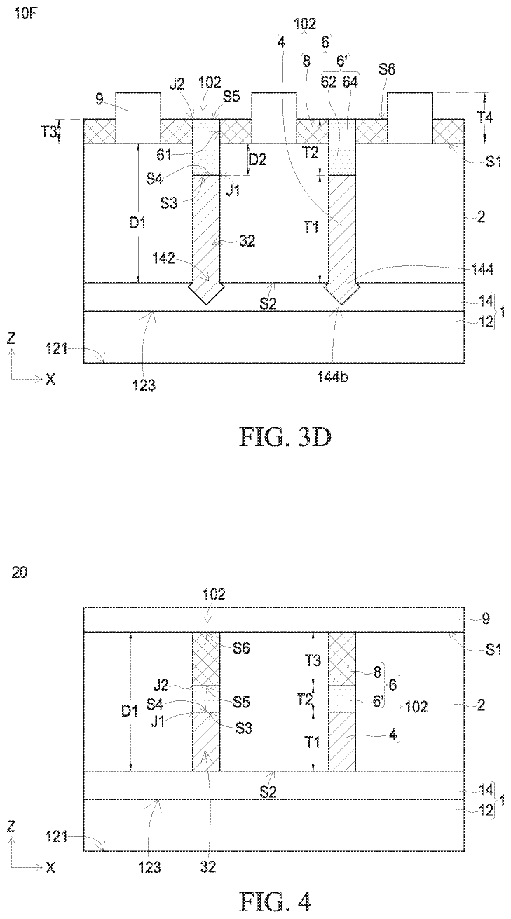

FIG. 3A shows a cross-sectional view of the semiconductor device 10A fabricated by process steps of FIGS. 1A-1H in accordance with an embodiment of the present disclosure. The semiconductor device 10A includes the substrate 1, the dielectric layer 2 on the substrate 1, the trench structure 3, the electrical connector 9, and a first epitaxy structure 102 located in the first trench 32 of the trench structure 3 and covered the first surface S1. The trench structure 3 are formed in the dielectric layer 2. The first epitaxy structure 102 includes the first semiconductor layer 4 and the second semiconductor layer 6, and the second semiconductor layer 6 includes the active portion 6′ and the doped portion 8. The first epitaxy structure 102 is formed on the substrate 1 and may connect to the second surface S2 of the first sublayer 14. Besides, the first epitaxy structure 102 is located in the dielectric layer 2 and may cover the first surface S1. More specifically, the first epitaxy structure 102 fills the first trench 32 and connects the electrical connector 9. The first semiconductor layer 4 connects the dielectric layer 2 and the second surface S2 of the first sublayer 14. When there are multiple electrical connectors 9, the first epitaxy structure 102 can be disposed between the electrical connectors 9.

As shown in FIGS. 2D and 3A, the first semiconductor layer 4 fills the first trench 32 along X-axis and Y-axis so the first semiconductor layer 4 and the first trench 32 have the same shape in the top view, such as rectangle. In one embodiment, the first semiconductor layer 4 is not completely fill the first trench 32 along Z-axis, i.e., the first semiconductor layer 4 is not protruding from the first trench 32. The first semiconductor layer 4 includes a third surface S3 away from the first sublayer 14, and there is a vertical distance D2 between the third surface S3 and the first surface S1 of the dielectric layer 2. The vertical distance D2 can be in a range of 50 nm to 2000 nm, such as 50 nm, 100 nm 150 nm, 200 nm, 500 nm, 1000 nm or 1500 nm.

Referring to FIG. 3A, the active portion 6′ has the first section 62 located in the first trench 32 and the second section 64 located on the first section 62 and protruding from the first surface S1 of the dielectric layer 2. In addition, the active portion 6′ includes a fourth surface S4 closer to the substrate 1 and a fifth surface S5 opposite to the fourth surface S4. The fourth surface S4 contacts the third surface S3 of the first semiconductor layer 4 to form a first junction J1 within the first trench 32. Meanwhile, the active portion 6′ and the doped portion 8 are connected to form a second junction J2 therebetween. In this embodiment, on the X-Z plane, the second junction J2 is parallel to the trench sidewall 31. In another embodiment, the second junction J2 may have an arc shape with curvature due to process characteristics. Besides, the doped portion 8 has a sixth surface S6 away from the substrate 1. In this embodiment, the sixth surface S6 of the doped portion 8 and the fifth surface S5 of the active portion 6′ are approximately coplanar, so as to improve quality of protection layer formed afterward or package yield.

The first trench 32 has the first depth D1 and the first semiconductor layer 4 has a first thickness T1 smaller than the first depth D1. In details, the first thickness T1 can be 50% to 95% of the first depth D1. In one embodiment, the first semiconductor layer 4 and the substrate 1 may be lattice mismatch, so as to induce defects formed in the first semiconductor layer 4 during the epitaxy process. More specifically, the first sublayer 14 and the first semiconductor layer 4 respectively have a first intrinsic lattice constant a1 and a second intrinsic lattice constant a2, and a lattice difference therebetween may be in a range of 1% to 15% calculated by

$$\vert \frac{a 2 - a 1}{a 1} \vert .$$

The term “intrinsic lattice constant” hereby means the lattice constant of a crystal structure without strain. The first semiconductor layer 4 can be InAlGaAs, AlGaInP or InGaSb, and the first sublayer 14 can be Si, Ge, GaAs or InP. Through disposition of the first trench 32, defect density of the first semiconductor layer 4 can be gradually reduced along Z-axis, from the second surface S2 towards the third surface S3. Thus, the upper portion of the first semiconductor layer 4 and the second semiconductor layer 6 formed thereon can have better crystalline quality so the light-emitting efficiency can be improved.

In the embodiment of FIG. 3A, the active portion 6′ has a second thickness T2, which includes a first section thickness T21 of the first section 62 and a second section thickness T22 of the second section 64 (T2=T21+T22). The second thickness T2 is smaller than the first depth D1 or the first thickness Ti. Besides, the doped portion 8 and the electrical connector 9 respectively have a third thickness T3 and a fourth thickness T4. In one embodiment, the fourth thickness T4 is greater than the third thickness T3 so that the electrical connector 9 can be higher than the doped portion 8 to facilitate the subsequent circuit wiring.

FIG. 3B shows a cross-sectional view of a semiconductor device 10D disclosed in one embodiment in accordance with the present disclosure, and the semiconductor device 10D is similar to the semiconductor device 10A. In this embodiment, by controlling growth speed of a preferred orientation during the epitaxy process, the active portion 6′ can grow upwards and protrude from the doped portion 8. In other words, the fifth surface S5 of the active portion 6′ is farther from the first surface S1 than the sixth surface S6 of the doped portion 8 and a part of the side surface 61 of the active portion 6′ does not contact the doped portion 8. The second portion thickness T22 is greater than the third thickness T3 and smaller than the fourth thickness T4. When the semiconductor device 10D is a light-absorbing device, the protruding active portion 6′ increases the light absorption area to achieve better sensing performance.

FIG. 3C shows a cross-sectional view of a semiconductor device 10E that is similar to the semiconductor device 10A. In this embodiment, the substrate 1 further includes a second sublayer 16 formed on the based layer 12. To be more specific, the second sublayer 16 is located between the base layer 12 and the first sublayer 14.

FIG. 3D shows a cross-sectional view of a semiconductor device 10F that is similar to the semiconductor device 10A. In this embodiment, after the first trenches 32 are formed in the dielectric layer 2 as shown in FIG. 1C, cavities 144 can be optionally formed in the first sublayer 14 of the substrate 1 by etching processes. For example, the first sublayer 14 can be treated by a dry etching process and then a wet etching process to form the cavities 144 thereon. The etchant used in the wet etching process can be acid or alkali, such as KOH, HF, buffered oxide etch (BOX) or aqua regia. Each of the cavities 144 is attached to one first trench 32, and includes a bottom 144b and second opening 142 connecting to the first trench 32. In one embodiment, the cavity 144 has a horizontal width (along X-axis) varied along Z-axis. For example, the value of the horizontal width is gradually increased from the second opening 142, then gradually reduced to the bottom 144b. By the disposition of the cavity 144, the aforementioned defects in the first semiconductor layer 4 caused by lattice mismatch can be greatly confined in the cavity 144 so the first semiconductor layer 4 in the first trench 32 has lower defect density than that in the cavity 144, and the second semiconductor layer 6 formed on the first semiconductor layer 4 can have better crystalline quality to improve light-emitting efficiency. Moreover, since the first semiconductor layer 4 in the cavity 144 has higher defect density, the electrical impedance between the first semiconductor layer 4 and the first sublayer 14 can be reduced. When the semiconductor device 1OF is a light-absorbing device, photoexcited electrons or holes can be transmitted to the first sublayer 14 easily because of the low electrical impedance, so as to improve the sensitivity and response of the semiconductor device 10F.

FIG. 4 shows a cross-sectional view of a semiconductor device 20 disclosed in one embodiment in accordance with the present disclosure, and the semiconductor device 20 is similar to the semiconductor device 10A in FIG. 3A. In this embodiment, the first epitaxy structure 102 are located in the first trench 32, and the electrical connector 9 covers the first trench 32 and the first epitaxy structure 102. More specifically, the first semiconductor layer 4 and the second semiconductor layer 6 are both located in the first trench 32. The active portion 6′ is located between the doped portion 8 and the first semiconductor layer 4, and the second semiconductor layer 6 does not exceed the first surface S1 of the dielectric layer 2. In this embodiment, the sixth surface S6 of the doped portion 8 and the first surface S1 of the dielectric layer 2 are substantially coplanar. The electrical connector 9 is formed on the second semiconductor layer 6 and contacts the sixth surface S6. The first thickness T1 may be equal or larger than the third thickness T3, and both are larger than the second thickness T2, i.e., T1≥T3>T2. When the semiconductor device 20 is a light-emitting device, lights generated by the active portion 6′ can be emitted from side surfaces of the semiconductor device 20 (along Y-axis) because of the coverage of the electrical connector 9. Similarly, when the semiconductor device 20 is a light-absorbing device, lights enter the active portion 6′ through the side surfaces of the semiconductor device 20.

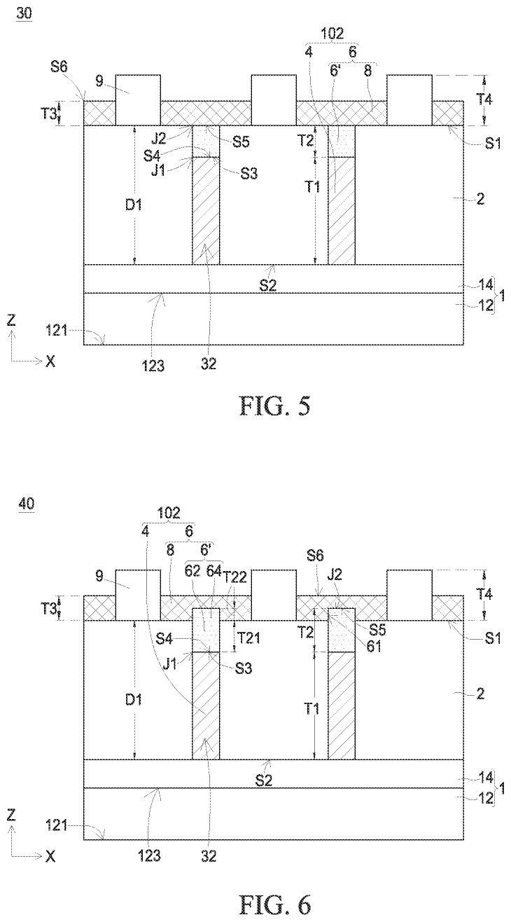

FIG. 5 shows a cross-sectional view of a semiconductor device 30 disclosed in one embodiment in accordance with the present disclosure and the semiconductor device 30 is similar to the semiconductor device 10A in FIG. 3A. In this embodiment, the fifth surface S5 of the active portion 6′ and the first surface S1 are substantially coplanar, and the doped portion 8 is located on the first surface S1 and covers the first trench 32. In this embodiment, the semiconductor device 30 is the light-emitting device, and the first thickness T1 is greater than the second thickness T2, while the second thickness T2 is equal or larger than the third thickness T3, i.e., T1>T2≥T3. Besides, the first depth D1 is substantially equal to the sum of the first thickness T1 and the second thickness T2 (D1=T1+T2).

FIG. 6 shows a cross-sectional view of a semiconductor device 40 disclosed in one embodiment in accordance with the present disclosure and the semiconductor device 40 is similar to the semiconductor device 30 in FIG. 5. In this embodiment, the active portion 6′ protrudes from the first trench 32 and includes the first section 62 and the second section 64, and the doped portion 8 is located on the first surface S1 and covers the second section 64. More specifically, the doped portion 8 horizontally surrounds the second section 64 (on the X-Y plane) and vertically covers the second section 64 (along Z-axis). Moreover, the first thickness T1 is greater than the second thickness T2, and the second thickness T2 is larger than the third thickness T3, i.e., T1>T2>T3. The first depth D1 is smaller than the sum of the first thickness T1 and the second thickness T2 (D1<T1+T2), but the sum of the first depth D1 and the third thickness T3 is larger than the sum of the first thickness T1 and the second thickness T2 (D1+T3>T1+T2). Besides, the third thickness T3 is larger than the second section thickness T22 of the second section 64. Compared with the semiconductor device 30 in FIG. 5, the active portion 6′ in this embodiment is closer to the sixth surface S6 of the doped portion 8, thus the light transmittance of the semiconductor device 40 can be better.

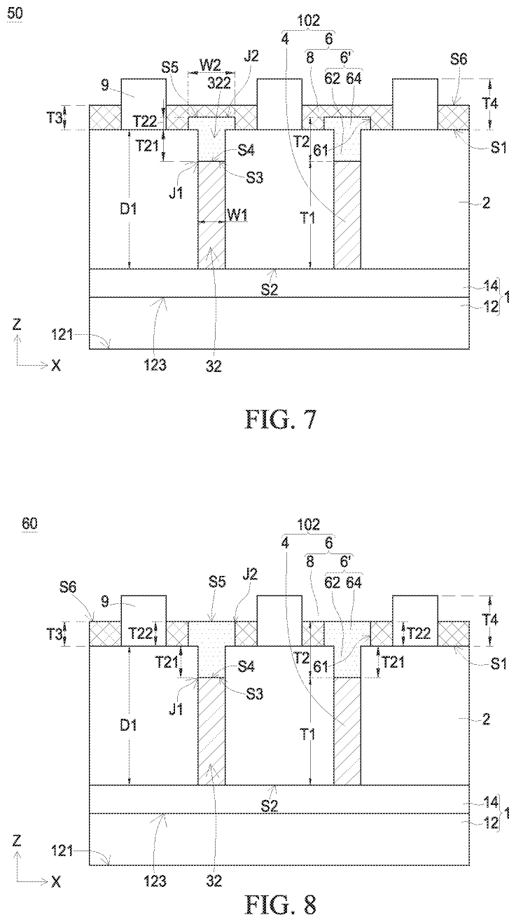

FIG. 7 shows a cross-sectional view of a semiconductor device 50 disclosed in one embodiment in accordance with the present disclosure and the semiconductor device 50 is similar to the semiconductor device 40 in FIG. 6. In this embodiment, the second semiconductor layer 6 protrudes from the first trench 32 and includes the first section 62 and the second section 64, and the doped portion 8 is located on the first surface S1 and covers the second section 64. The active portion 6′ has a second width W2 which is larger than the first width W1 of the first trench 32 and the second section 64 of the active portion 6′ contacts the first surface S1.

FIG. 8 shows a cross-sectional view of a semiconductor device 60 disclosed in one embodiment in accordance with the present disclosure and the semiconductor device 60 is similar to the semiconductor device 50 in FIG. 7. In this embodiment, the second semiconductor layer 6 protrudes from the first trench 32 and includes the second section 64, and the second section thickness T22 is approximately equal to the third thickness T3 of the doped portion 8. In other words, the fifth surface S5 of the active portion 6′ is not covered by the doped portion 8. Meanwhile, the second section 64 contacts the first surface S1 of the dielectric layer 2.

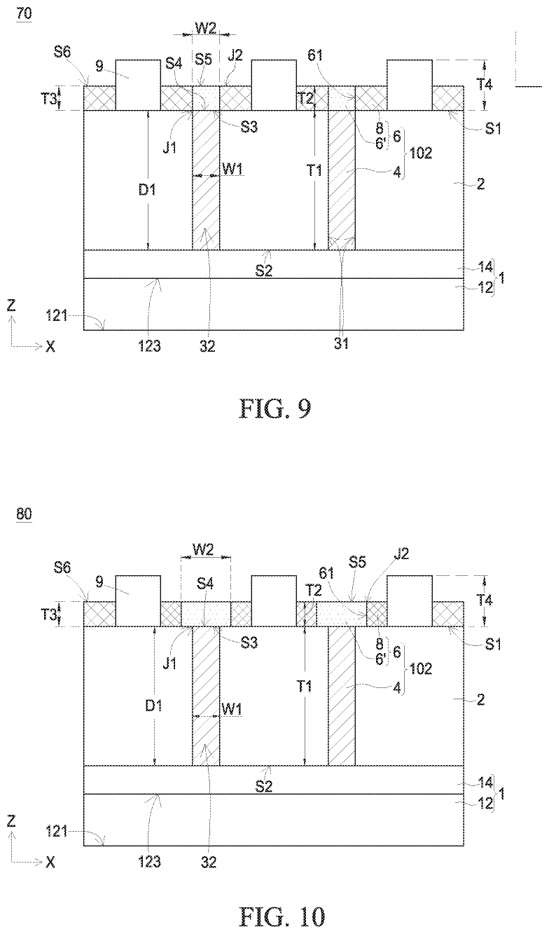

FIG. 9 shows a cross-sectional view of a semiconductor device 70 disclosed in one embodiment in accordance with the present disclosure and the semiconductor device 70 is similar to the semiconductor device 10A in FIG. 3A. In this embodiment, the first semiconductor layer 4 fills up the first trench 32, i.e., the first thickness T1 of the first semiconductor layer 4 is equal to the first depth D1 of the first trench 32. The third surface S3 and the first surface S1 are approximately coplanar. The second semiconductor layer 6 is located on the first surface S1 and covers the first trench 32 and the first semiconductor layer 4. Besides, the second thickness T2 of the active portion 6′ can be equal to the third thickness T3 of the doped portion 8 and the second width W2 of the active portion 6′ is same as the first width W1 of the first trench 32.

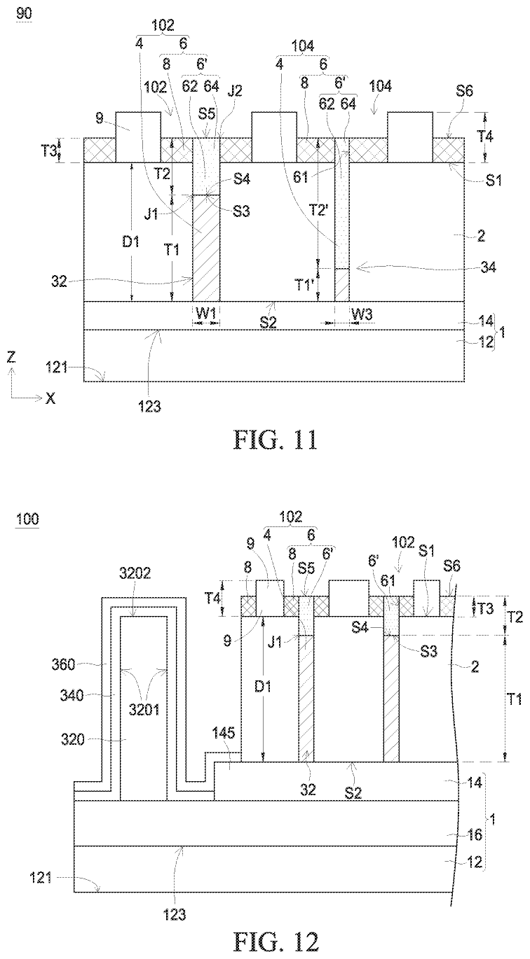

FIG. 10 shows a cross-sectional view of a semiconductor device 80 disclosed in one embodiment in accordance with the present disclosure and the semiconductor device 80 is similar to the semiconductor device 70 in FIG. 9. In this embodiment, the first semiconductor layer 4 fills the first trench 32 up and the second semiconductor layer 6 is located on the first surface S1. The third surface S3 and the first surface S1 are approximately coplanar. Besides, the second width W2 of the active portion 6′ is larger than the first width W1 of the first trench 32. In other words, the active portion 6′ contacts the first surface S1 of the dielectric layer 2.

FIG. 11 shows a cross-sectional view of a semiconductor device 90 disclosed in one embodiment in accordance with the present disclosure and the semiconductor device 90 is similar to the semiconductor device 10A in FIG. 3A. In this embodiment, the trench structure 3 includes the first trench 32 and a second trench 34 for growing a first epitaxy structure 102 and a second epitaxy structure 104 respectively, and the first trench 32 and the second trench 34 respectively have the first width W1 and a third width W3. The first epitaxy structure 102 and the second epitaxy structure 104 are grown simultaneously by same process steps shown in FIGS. 1A-1H, and the second epitaxy structure 104 also includes the first semiconductor layer 4, the active portion 6′ and the doped portion 8. The first width W1 is different from the third width W3. In one embodiment, the first width W1 is greater than the third width W3. During the epitaxy processes of FIGS. 1D-1E, the first trench 32 can accommodate more reactive gas than the second trench 34 so the epitaxy growth in the first trench 32 is faster than in the second trench 34. The first semiconductor layer 4 grown in the first trench 32 and in the second trench 34 respectively has the first thickness T1 and T1′, and T1>T1′. Subsequently, the second semiconductor layer 6 grown in the first trench 32 also has a thickness greater than that of in the second trench 34. Then a chemical-mechanical planarization (CMP) process is applied to make the first epitaxy structure 102 and the second epitaxy structure 104 have substantially the same thickness so that the active portion 6′ in the first trench 32 and in the second trench 34 respectively have the second thickness T2 and T2′, and T2<T2′.

Through width difference between the first trench 32 and the second trench 34, epitaxy structures having different chemical composition can be grown at the same time in one process flow. In one embodiment, both the first epitaxy structure 102 and the second epitaxy structure 104 includes same constituents, such as InxGa₍₁₋ₓ₎N (0≤x≤1). The active portion 6′ in the first trench 32 includes Inₓ₁Ga₍₁₋ₓ₂₎N, while the active portion 6′ in the second trench 34 includes Inₓ₂Ga₍₁₋ₓ₂₎N, and x1>x2. When x1 is in a range of 0.4 to 0.85, the active portion 6′ in the first trench 32 can emit red lights with a wavelength between 610 nm˜700 nm. When x2 is in a range of 0.2 to 0.34, the active portion 6′ in the second trench 34 can emit green lights with a wavelength between 490 nm˜550 nm. Alternatively, x2 can be in a range of 0.05 to 0.2 to make the active portion 6′ in the second trench 34 emit blue lights with a wavelength between 400 nm 490 nm. Thus, the semiconductor device 90 can simultaneously emit red light and green light, or red light and blue light. In one embodiment, the semiconductor device 90 may further include a third trench and a third epitaxy structure grown in the third trench (not shown). By controlling width of the trenches, the first epitaxy structure 102, the second epitaxy structure 104 and the third epitaxy structure can respectively emit red light, green light and blue light to form a mixed white light.

In other embodiments, the first epitaxy structure 102 and the second epitaxy structure 104 can respectively include different constituents. For example, the first semiconductor layer 4 of the first epitaxy structure 102 can be InAlGaAs, while the first semiconductor layer 4 of the second epitaxy structure 104 can be AlGaInP or InGaSb.

FIG. 12 shows a cross-sectional view of a semiconductor apparatus 100 disclosed in one embodiment in accordance with the present disclosure. The semiconductor apparatus 100 includes the substrate 1, the dielectric layer 2 located on the substrate 1, the first epitaxy structure 102 formed in the dielectric layer 2, the electrical connector 9 connecting the first epitaxy structure 102, a fin 320, an insulating layer 340 and a metal layer 360. More specifically, the substrate 1 includes the base layer 12, the first sublayer 14 and the second sublayer 16. The fin 320 is located on the second sublayer 16 and not connected to the first sublayer 14 and the dielectric layer 2. The fin 320 includes fin sidewalls 3201 and a fin top surface 3202, and the fin 320 and the first sublayer 14 can include same material or different materials. The insulating layer 340 covers the fin sidewalls 3201 and the fin top surface 3202, then the metal layer 360 covers the insulating layer 340 and a part of the first sublayer 14. In one embodiment, the metal layer 360 may connect to the dielectric layer 2. Besides, according to requirements of wiring design, the fin 320 may connect to the first sublayer 14. Details of the dielectric layer 2, the first epitaxy structure 102 and the electrical connector 9 are described in aforementioned embodiments of the present disclosure.

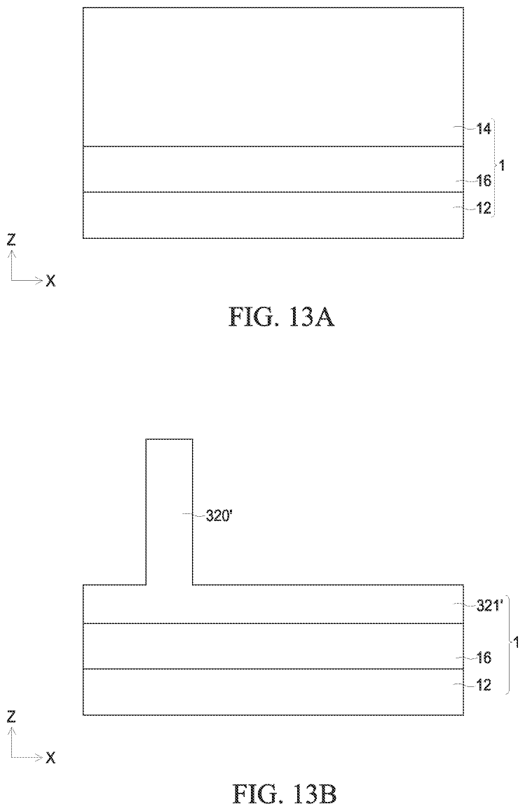

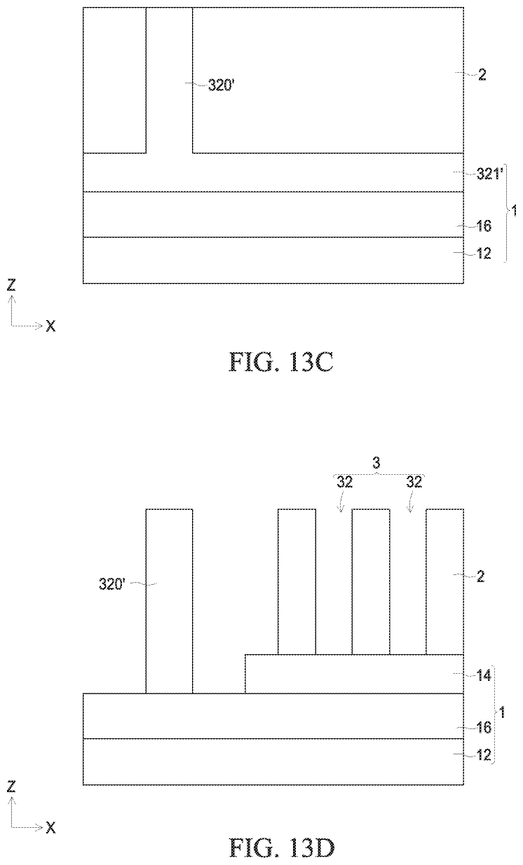

Referring to FIGS. 13A-13D for schematic diagrams of manufacturing process of the semiconductor apparatus 100 in one embodiment in accordance with the present disclosure. In the step of FIG. 13A, the substrate 1 which includes the base layer 12, a first thick sublayer 14′ and the second sublayer 16 is provided. In the step of FIG. 13B, the first thick sublayer 14′ is etched to form a fin portion 320′ and a platform portion 321′. In the step of FIG. 13C, the dielectric layer 2 is formed on the fin portion 320′ and the platform portion 321′ by the deposition process, and the CMP process can be optionally applied to expose the fin portion 320′. Then, in the step of FIG. 13D, the etching process is implemented to form the trench structure 3 on the dielectric layer 2, and the platform portion 321′ is also etched to form the fin 320 and the first sublayer 14 separated from the fin 320. Afterwards, the first epitaxy structure 102 and the electrical connector 9 are formed by process steps of FIGS.1D-1H, then the insulating layer 340 and the metal layer 360 are formed in sequence by deposition process to form the semiconductor apparatus 100 shown in FIG. 12. The fin 320 may be further processed to become different types of transistor. Through process steps of FIGS. 13A-13D, semiconductor devices and transistors fabrication can be integrated into one process flow, so as to save traditional assembly and package processes and simplify manufacture of the semiconductor apparatus 100. For instance, to fabricate a light detector, the photodiode array and the transistors can be manufactured on the same substrate by the present disclosure to save the assembly processes such as die mount or wire bonding.

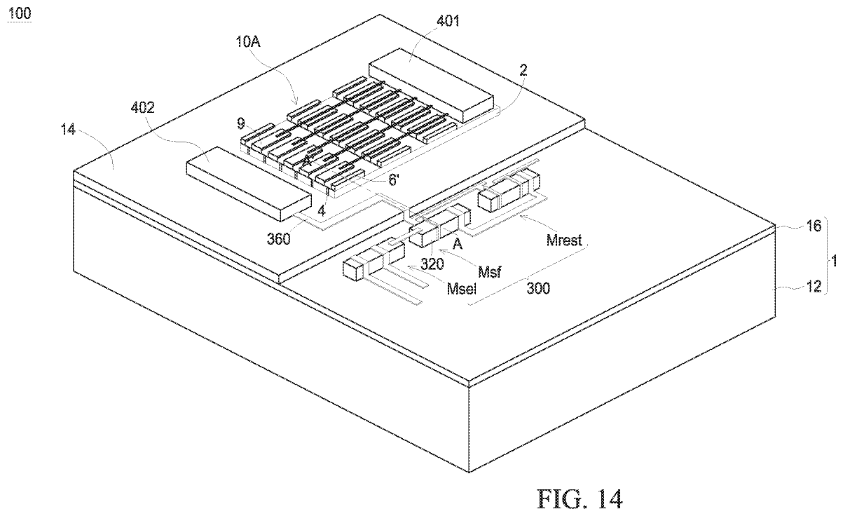

FIG. 14 shows a cross-sectional view of the semiconductor apparatus 100 disclosed in one embodiment in accordance with the present disclosure, and FIG. 12 is the cross-sectional view along A-A′ line in FIG. 14. The semiconductor apparatus 100 further includes a first pad 401, a second pad 402 and a plurality of transistors 300. The first pad 401 is located on the dielectric layer 2 and electrically connects to the first epitaxy structure 102 and the electrical connector 9. The second pad 402 is disposed on the first sublayer 14 and electrically connects to the fin 320. In one embodiment, the first pad 401 can be applied a ground voltage (Vss). The plurality of transistors 300 is disposed on the second sublayer 16, and the plurality of transistors 300 can be fin field-effect transistors (FinFET) which include the fin 320. In one embodiment, the plurality of transistors 300 includes a source follower transistor Msf, a reset transistor Mrest and a selection transistor Msel to form a control circuit. The metal layer 360 electrically connects the gate of the source follower transistor Msf and the source/drain of the reset transistor Mrest. The source and drain of the source follower transistor Msf electrically connect the source/drain of the reset transistor Mrest and the source/drain of the selection transistor Msel. Meanwhile, the gate of the reset transistor Mrest and the gate and source/drain of the selection transistor Msel are electrically connected to an exterior circuit which provides an operating voltage (V_{DD}), a reset voltage (Vᵣₛₜ) or the ground voltage (V_{SS}). Through above circuit arrangement, the semiconductor apparatus 100 becomes a simple optoelectronic integrated circuit (OEIC) that can be applied as a light-emitting array or a light-absorbing array. In other embodiment, the quantity of the transistors 300, types of the transistors 300 and the circuit arrangement can be modified according to design requirements to achieve specific function.

For all the embodiments mentioned above, the base layer 12 and the first sublayer 14 can be semiconductors, and the base layer 12 and the first sublayer 14 can be same material or different materials. The semiconductors can include but not limited to IV semiconductors or III-V semiconductors, such as Si, Ge, SiGe, GeSn, SiC, GaN, GaP, GaAs, AsGaP or InP. More specifically, the first sublayer 14 can include but is not limited to Si, Ge, SiGe or GeSn. In one embodiment, the first sublayer 14 includes Si and the second surface S2 has a specific crystal plane, which can include but is not limited to (111), (100), (010), (001).

For all the embodiments mentioned above, the second sublayer 16 can be semiconductors or insulating materials. The insulating materials can include but are not limited to oxides, nitrides and halides, such as Al₂O₃, SiO₂, SiOₓN_{y}, TiO₂, Nb₂O₅, HfO₂, ZrO₂, Ta₂O₅, SiNₓ, SiOₓN_{y}, TiNₓ, TaN or MgF₂. In the embodiment that the second sublayer 16 is a semiconductor, the composition of the semiconductor can be gradation. For instance, the second sublayer 16 can be Si₍₁₋ₓ₎Geₓ or InₓGa₍₁₋ₓ₎N and 0.1<x<1, wherein the x value is increased along Z-axis towards the first sublayer 14. Thus, the second sublayer can be a buffer of lattice mismatch between the base layer 12 and the first sublayer 14. In the embodiment that the second sublayer 16 is an insulating material, the base layer 12 is electrically isolated from the first sublayer 14 to reduce leakage current.

For all the embodiments mentioned above, the dielectric layer 2 can be the aforementioned insulating materials, and the dielectric layer 2 and the first sublayer 14 are different materials. For instance, the first sublayer 14 can be Ge and the dielectric layer 2 can be SiO₂ or SiNₓ.

For all the embodiments mentioned above, the first semiconductor layer 4 and the second semiconductor layer 6 can include but are not limited to III-V semiconductors, such as GaAs, InP, InGaAs, AlGaAs, AlGaInAs, GaP, InGaP, InGaSb, AlInP, AlGaInP, InA1GaAs, GaN, InGaN, AlGaN, AlGaInN, AlAsSb, InGaAsP, InGaAsN or AlGaAsP.

For all the embodiments mentioned above, the doped layer 7 can include Si, C, Se, Te, Zn, Mg, Be, ZnO or MgO. The first dopant and the second dopant can include Si, C, Se, Te, Zn, Mg or Be.

For all the embodiments mentioned above, the electrical connector 9, the metal layer 360, the first pad 401 and the second pad 402 can be metals or metal oxides. The metals can include but are not limited to Cu, Al, Cr, Sn, Au, Ni, Ti, Pt, Pb, Zn, Cd, Sb, Co or alloys including any of the aforementioned metals. The metal oxides can include but are not limited to ITO, InO, SnO, CTO, ATO, AZO, ZTO, GZO, IWO, IZO or combination of any of the aforementioned metal oxides.

For all the embodiments mentioned above, the insulating layer 340 can be the insulating materials mentioned above, such as Al₂O₃, Nb₂O₅, HfAlOₓ, HfSiOₓ or HfO₂.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a dielectric layer having a first surface;
a first trench located in the dielectric layer;
a first semiconductor layer located in the first trench;
a second semiconductor layer comprising an active portion connecting to the first semiconductor layer; and
an electrical connector located on the first surface and connected to the second semiconductor layer.

2. The semiconductor device according to claim 1, wherein the electrical connector covers the first trench.

3. The semiconductor device according to claim 1, further comprising a first junction formed between the first semiconductor layer and the active portion, wherein the first junction is located in the first trench.

4. The semiconductor device according to claim 1, wherein the active portion comprises a first section in the first trench and a second section protruding from the first trench.

5. The semiconductor device according to claim 1, wherein the active portion contacts the first surface of the dielectric layer.

6. The semiconductor device according to claim 1, wherein the second semiconductor layer further comprises a doped portion located on the first surface and connecting to the active portion.

7. The semiconductor device according to claim 6, wherein the doped portion covers the first trench.

8. The semiconductor device according to claim 4, wherein the second semiconductor layer further comprises a doped portion covering the second section.

9. The semiconductor device according to claim 1, wherein the first trench, the first semiconductor layer and the active portion respectively have a depth, a first thickness and a second thickness, and a sum of the first thickness and the second thickness is greater than the depth.

10. The semiconductor device according to claim 9, wherein the first thickness is substantially equal to the depth.

11. The semiconductor device according to claim 9, wherein the second semiconductor layer further comprises a doped portion located on the first surface and having a third thickness, and a sum of the first thickness and the second thickness is substantially equal to a sum of the depth and the third thickness.

12. The semiconductor device according to claim 11, wherein the electrical connector has a fourth thickness, and the fourth thickness is greater than the third thickness.

13. The semiconductor device according to claim 1, further comprising a second trench in the dielectric layer, wherein the first trench and the second trench respectively have a first width and a second width, and the first width is different from the second width.

14. The semiconductor device according to claim 13, wherein the first width is greater than the second width, the first semiconductor layer is located in the second trench and a thickness of the first semiconductor layer in the first trench is greater than that of the first semiconductor layer in the second trench.

15. The semiconductor device according to claim 13, wherein the first semiconductor layers located in the first trench and the second trench have different chemical composition.

16. The semiconductor device according to claim 13, wherein the second semiconductor layers located in the first trench and the second trench have different chemical composition.

17. The semiconductor device according to claim 1, further comprising a substrate having a first sublayer, wherein the dielectric layer is formed on the first sublayer.

18. The semiconductor device according to claim 17, wherein the first sublayer of the substrate comprises a cavity connecting to the first trench, and the first semiconductor layer is located in the first trench and the cavity.

19. The semiconductor device according to claim 17, wherein the substrate further comprises a base layer and a second sublayer located between the first sublayer and the base layer.

20. A semiconductor apparatus, comprising:
a substrate comprising a first sublayer;
a semiconductor device of claim 1; and
a transistor comprising a fin, wherein the fin and the first sublayer have the same material.
